(19) United States
(12) Patent Application Publication
(10) Pub. No.: US 2020/0006207 A1
(43) Pub. Date: Jan. 2, 2020

(54) SEMICONDUCTOR DEVICE, CHIP-SHAPED SEMICONDUCTOR ELEMENT, ELECTRONIC DEVICE PROVIDED WITH SEMICONDUCTOR DEVICE, AND METHOD OF MANUFACTURING SEMICONDUCTOR DEVICE

(71) Applicant: SONY SEMICONDUCTOR SOLUTIONS CORPORATION, KANAGAWA (JP)

(72) Inventors: JO UMEZAWA, KAGOSHIMA (JP); HIROKI TSUNEMI, KAGOSHIMA (JP)

(21) Appl. No.: 16/484,581

(22) PCT Filed: Jan. 19, 2018
(86) PCT No.: PCT/JP2018/001566

§ 371 Date: Aug. 8, 2019

(30) Foreign Application Priority Data
Feb. 17, 2017 (JP) 2017-027830

(51) Int. Cl. H01L 23/498; H01L 21/56; H01L 23/00; H01L 23/16; H01L 23/538

(52) U.S. Cl. CPC H01L 23/49816; H01L 21/563; H01L 24/14; H01L 2225/06513; H01L 23/16; H01L 23/5385; H01L 24/11

(57) ABSTRACT

A semiconductor device includes a wiring board and a chip-shaped semiconductor element flip-chip mounted on the wiring board, in which a plurality of solder bumps and a plurality of protrusions including an insulating material are provided on a surface of the chip-shaped semiconductor element on a side facing the wiring board, and the chip-shaped semiconductor element is arranged so as to face the wiring board via an underfilling material in a state in which the underfilling material having a characteristic that viscosity decreases with an increase in temperature is applied to the wiring board and then subjected to reflow treatment to be flip-chip mounted on the wiring board.

### TECHNICAL FIELD

The present disclosure relates to a semiconductor device, a chip-shaped semiconductor element, an electronic device provided with a semiconductor device, and a method of manufacturing a semiconductor device.

### BACKGROUND ART

With miniaturization and thinning of electronic devices, miniaturization and thinning of a package including a chip-shaped semiconductor element with many terminals are also required. Therefore, a flip-chip mounting system to join a chip-shaped semiconductor element (hereinafter sometimes simply referred to as a chip) to a wiring board such as an interposer board by using a solder bump or the like is suggested.

First, a mounting system using a so-called capillary underfilling system is described in which the chip and the wiring board are electrically joined, and then a liquid-shaped underfilling material is applied to a periphery of the chip, and the underfilling material is allowed to penetrate in a gap between the wiring board and the chip using a capillary action. A basic process in this mounting system is illustrated in FIG. 28A.

When solder joint is performed between the chip and the wiring board, it is necessary to apply flux treatment to remove an oxide film on a metal surface. However, residual flux causes deterioration in reliability in an underfill sealing process. Therefore, after joining the chip and the wiring board, cleaning treatment is performed to remove the residual flux. Next, the liquid-shaped underfilling material is applied to the periphery of the chip, and the underfilling material is allowed to penetrate in the gap between the wiring board and the chip using the capillary action. Then, thereafter, the underfilling material is subjected to cure treatment to be cured and sealed. For example, Japanese Patent Application Laid-Open No. 2007-324418 and Japanese Patent Application Laid-Open No. 2008-270257 disclose that a protrusion different from electrodes is formed on the chip for the purpose of preventing short circuit between the electrodes and improving fluidity of the underfilling material by the capillary underfilling system.

In the capillary underfilling system, the underfilling material is allowed to penetrate in the gap between the wiring board and the chip using the capillary action. Therefore, if the gap is narrowed or a joint portion between the wiring board and the chip is narrowed, wettability of the underfilling material is deteriorated due to residue of the flux and the like, and the penetration of the underfilling material is inhibited. Therefore, there is a limit to narrow a pitch in a case of using sealing by the capillary underfilling system. Furthermore, a sealing process by the capillary underfilling system requires a relatively long time, and a process such as cleaning of the flux is also required, so that there is a problem that it is difficult to improve productivity by shortening a takt time in a production process in the mounting system using the capillary underfilling system.

For this reason, a mounting system based on a previous application system of the underfilling material in which the underfilling material is previously applied, and then the chip and the wiring board are electrically joined is disclosed in, for example, Japanese Patent Application Laid-Open No. 2002-203874. A basic process in this mounting system is illustrated in FIG. 28B.

The previous application system of the underfilling material has an advantage that the cleaning treatment of the residual flux is not required, and sealing may be performed even if the gap between the wiring board and the chip is narrowed or the joint portion between the wiring board and the chip is narrowed.

### CITATION LIST

### Patent Document

Patent Document 1: Japanese Patent Application Laid-Open No. 2007-324418

Patent Document 2: Japanese Patent Application Laid-Open No. 2008-270257

Patent Document 3: Japanese Patent Application Laid-Open No. 2002-203874

### SUMMARY OF THE INVENTION

### Problems To Be Solved by the Invention

According to the technology disclosed in Patent Document 3 described above, it is required to selectively apply the underfilling material or to mount the chip by pressurizing under heating after the wiring board and the chip are positioned with high accuracy. However, from a viewpoint of productivity improvement, it is preferable that chip mounting may be performed without the need for selective application of the underfilling material and positioning with high accuracy.

Furthermore, in the previous application system of the underfilling material, in the chip mounting process, voids are likely to remain in the underfilling material due to a reduction action of the flux function and the like. However, in the technology disclosed in Patent Document 3 described above, only an effect by a decrease in viscosity of the underfilling material is mentioned regarding how the voids remaining in the underfilling material at the time of chip mounting are allowed to escape outside.

Therefore, an object of the present disclosure is to provide a semiconductor device which does not require selective application of an underfilling material or positioning with high accuracy, and may further reduce voids in the underfilling material at the time of chip mounting, an electronic device provided with the semiconductor device, a chip-shaped semiconductor element used in the semiconductor device, and a method of manufacturing the semiconductor device.

### Solutions to Problems

A semiconductor device according to a first aspect of the present disclosure for achieving the above-described object is

a semiconductor device including:

a wiring board; and

a chip-shaped semiconductor element flip-chip mounted on the wiring board,

in which a plurality of solder bumps and a plurality of protrusions including an insulating material are provided on a surface of the chip-shaped semiconductor element on a side facing the wiring board, and

the chip-shaped semiconductor element is arranged so as to face the wiring board via an underfilling material in a state in which the underfilling material having a characteristic that viscosity decreases with an increase in temperature is applied to the wiring board and then subjected to reflow treatment to be flip-chip mounted on the wiring board.

A chip-shaped semiconductor element according to the first aspect of the present disclosure for achieving the above-described object is a chip-shaped semiconductor element flip-chip mounted on a wiring board to which an underfilling material is applied,

in which a plurality of solder bumps and a plurality of protrusions including an insulating material are provided on a surface of the chip-shaped semiconductor element on a side facing the wiring board.

An electronic device according to a first aspect of the present disclosure for achieving the above-described object is an electronic device provided with a semiconductor device including a wiring board and a chip-shaped semiconductor element flip-chip mounted on the wiring board,

in which a plurality of solder bumps and a plurality of protrusions including an insulating material are provided on a surface of the chip-shaped semiconductor element on a side facing the wiring board, and

the chip-shaped semiconductor element is arranged so as to face the wiring board via an underfilling material in a state in which the underfilling material having a characteristic that viscosity decreases with an increase in temperature is applied to the wiring board and then subjected to reflow treatment to be flip-chip mounted on the wiring board.

A method of manufacturing a semiconductor device according to a first aspect of the present disclosure for achieving the above-described object is a method of manufacturing a semiconductor device, including:

arranging a chip-shaped semiconductor element provided with a plurality of solder bumps and a plurality of protrusions including an insulating material on a surface on a side facing a wiring board so as to face the wiring board via an underfilling material in a state in which the underfilling material having a characteristic that viscosity decreases with an increase in temperature is applied to the wiring board, and then applying reflow treatment to flip-chip mount the same on the wiring board.

### Effects of the Invention

In a chip-shaped semiconductor element used in a semiconductor device of the present disclosure, a plurality of solder bumps and a plurality of protrusions including an insulating material are provided on a surface on a side facing a wiring board. Then, the chip-shaped semiconductor element is arranged so as to face the wiring board via an underfilling material in a state in which the underfilling material having a characteristic that viscosity decreases with an increase in temperature is applied to the wiring board, and thereafter subjected to reflow treatment to be mounted. It is possible to perform chip mounting without the need for selective application of the underfilling material or positioning with high accuracy, because position correction by self-alignment is possible without the need for a heating/pressurizing process for individual chips. Furthermore, a clearance between the protrusions of the chip-shaped semiconductor element serves as a gas flow path at the time of reflow treatment, so that voids of the underfilling material may be reduced at the time of chip mounting.

### BRIEF DESCRIPTION OF DRAWINGS

FIG. 1 is a schematic exploded perspective view for explaining a semiconductor device according to a first aspect of the present disclosure.

FIG. 2 is a process chart for explaining the basic manufacturing process of the semiconductor device according to the first aspect of the present disclosure.

FIGS. 3A and 3B are schematic perspective views for explaining an arrangement of electrodes and protrusions of the chip-shaped semiconductor element. FIG. 3A illustrates a state before the protrusions are formed, and FIG. 3B illustrates a state after the protrusions are formed.

FIG. 4 is a schematic perspective view for explaining an electrode arrangement of a wiring board.

FIG. 5 is a schematic perspective view for explaining an arrangement of electrodes of the wiring board and a previously applied underfilling material layer.

FIGS. 6A to 6E are schematic partial cross-sectional views for explaining a process of manufacturing the semiconductor device.

FIGS. 7A to 7C are schematic partial cross-sectional views for explaining the process of manufacturing the semiconductor device following FIG. 6E.

FIGS. 8A to 8D are schematic partial cross-sectional views for explaining the process of manufacturing the semiconductor device.

FIG. 9 is a schematic plan view for explaining a structure of a chip-shaped semiconductor element according to a second embodiment.

FIG. 10 is a schematic plan view for explaining a structure of a chip-shaped semiconductor element according to a third embodiment.

FIG. 11 is a schematic plan view for explaining a structure of a chip-shaped semiconductor element according to a fourth embodiment.

FIGS. 12A and 12B are schematic plan views for explaining a structure of a chip-shaped semiconductor element according to the fifth embodiment, in which FIG. 12A illustrates an arrangement relationship of electrodes and FIG. 12B illustrates an arrangement relationship of protrusions.

FIG. 13 is a schematic plan view for explaining the structure of the chip-shaped semiconductor element according to the fifth embodiment, illustrating an arrangement relationship of the electrodes and protrusions.

FIGS. 14A and 14B are schematic plan views for explaining a structure of a chip-shaped semiconductor element according to a sixth embodiment, in which FIG. 14A illustrates an arrangement relationship of electrodes and FIG. 14B illustrates an arrangement relationship of protrusions.

FIG. 15 is a schematic plan view for explaining the structure of the chip-shaped semiconductor element according to the sixth embodiment, illustrating an arrangement relationship of the electrodes and protrusions.

FIGS. 16A and 16B are schematic plan views for explaining a structure of a chip-shaped semiconductor element according to a seventh embodiment, in which FIG. 16A illustrates an arrangement relationship of electrodes and FIG. 16B illustrates an arrangement relationship of protrusions.

FIG. 17 is a schematic plan view for explaining the structure of the chip-shaped semiconductor element according to the seventh embodiment, illustrating an arrangement relationship of the electrodes and protrusions.

FIGS. 18A and 18B are schematic plan views for explaining a structure of a chip-shaped semiconductor element according to an eighth embodiment, in which FIG. 18A illustrates an arrangement relationship of electrodes and FIG. 18B illustrates an arrangement relationship of protrusions.

FIG. 19 is a schematic plan view for explaining the structure of the chip-shaped semiconductor element according to the eighth embodiment, illustrating an arrangement relationship of the electrodes and protrusions.

FIG. 20 is a schematic plan view for explaining a structure of a semiconductor device according to a ninth embodiment provided with a pair of chip-shaped semiconductor elements.

FIGS. 21A and 21B are schematic plan views for explaining a structure of one of the pair of chip-shaped semiconductor elements according to the ninth embodiment, in which FIG. 21A illustrates an arrangement relationship of electrodes and FIG. 21B illustrates an arrangement relationship of protrusions.

FIGS. 22A and 22B are schematic plan views for explaining a structure of the other of the pair of chip-shaped semiconductor elements according to the ninth embodiment, in which FIG. 22A illustrates an arrangement relationship of electrodes and FIG. 22B illustrates an arrangement relationship of protrusions.

FIGS. 23A and 23B are schematic partial cross-sectional views for explaining a process of manufacturing a semiconductor device according to a tenth embodiment.

FIG. 24 is a schematic diagram for explaining a structure of a protruding portion of a chip-shaped semiconductor element according to an eleventh embodiment.

FIGS. 25A and 25B are schematic diagrams for explaining a function of the protruding portion of the chip-shaped semiconductor element according to the eleventh embodiment.

FIG. 26 is a view of a twelfth embodiment, a schematic perspective view of an electronic device in which the semiconductor device according to the present disclosure is used.

FIG. 27 is a schematic block diagram illustrating a circuit configuration of the electronic device illustrated in FIG. 26.

FIGS. 28A and 28B are process charts for explaining a process of manufacturing a semiconductor device.

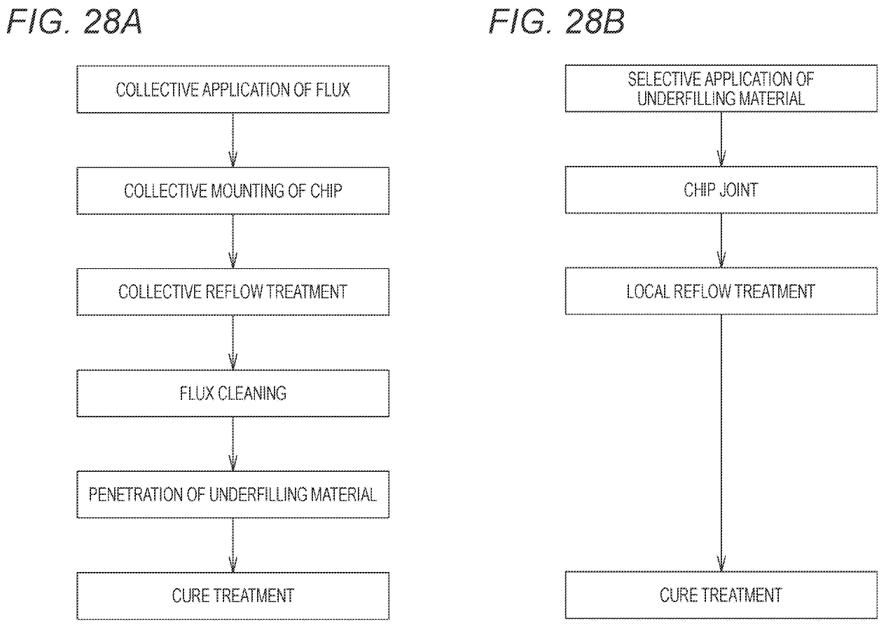

### MODE FOR CARRYING OUT THE INVENTION

Hereinafter, the present disclosure is described on the basis of embodiments with reference to the drawings. The present disclosure is not limited to the embodiments, and various numerical values and materials in the embodiments are examples. In the following description, the same reference sign is used for the same elements or elements having the same function, and the description is not repeated. Note that the description is given in the following order.
1. Overall Description of Semiconductor Device, Chip-shaped Semiconductor Element, Electronic Device Provided with Semiconductor Device, and Method of Manufacturing Semiconductor Device According to Present Disclosure
2. First Embodiment
3. Second Embodiment
4. Third Embodiment
5. Fourth Embodiment
6. Fifth Embodiment
7. Sixth Embodiment
8. Seventh Embodiment
9. Eighth Embodiment
10. Ninth Embodiment
11. Tenth Embodiment
12. Eleventh Embodiment
13. Twelfth Embodiment
14. Others

[Overall Description of Semiconductor Device, Chip-Shaped Semiconductor Element, Electronic Device Provided with Semiconductor Device, and Method of Manufacturing Semiconductor Device According to Present Disclosure]

In a semiconductor device according to the present disclosure, a semiconductor device used in an electronic device according to the present disclosure, and a semiconductor device manufactured by a method of manufacturing a semiconductor device according to the present disclosure (hereinafter, they are sometimes simply referred to as the semiconductor devices of the present disclosure), a chip-shaped semiconductor element may include a protrusion formed so that a tip end does not reach a wiring board in a state in which the chip-shaped semiconductor element is flip-chip mounted.

In the semiconductor device of the present disclosure including the above-described preferable configuration, the chip-shaped semiconductor element may be mounted in a state positioned with respect to the wiring board by fusion of a solder bump provided on the wiring board with a solder bump provided on the chip-shaped semiconductor element by reflow treatment.

In the semiconductor device of the present disclosure including the above-described various preferable configurations, an underfilling material may be selectively applied or may be collectively applied to the wiring board. From a viewpoint of improving productivity, this is preferably collectively applied to the wiring board.

In the semiconductor device of the present disclosure including the various preferable configurations described above, the underfilling material preferably has a flux function. According to this configuration, an oxide on a metal surface which is in contact with the underfilling material is removed, so that the fusion of the solder bumps by the reflow treatment may be excellently performed.

As described above, the chip-shaped semiconductor element according to the present disclosure is the chip-shaped semiconductor element flip-chip mounted on the wiring board to which the underfilling material is applied. A plurality of solder bumps and a plurality of protrusions including an insulating material are provided on a surface of the chip-shaped semiconductor element on a side facing the wiring board. Then, a configuration with the protrusions formed so that the tip ends do not reach the wiring board in a state in which the chip-shaped semiconductor element is flip-chip mounted may be realized.

The chip-shaped semiconductor element according to the present disclosure and the chip-shaped semiconductor element used in a semiconductor chip of the present disclosure (hereinafter, they are sometimes simply referred to as the chip-shaped semiconductor element of the present disclosure) may have the protrusion formed so as to be higher than the solder bump provided on the chip-shaped semiconductor element, the protrusion formed so as to be as high as the solder bump, or the protrusion formed so as to be lower than the solder bump.

In the chip-shaped semiconductor element of the present disclosure having the various preferable configurations described above, the protrusions may be provided at a constant density in a region where the protrusions are arranged on the surface of the chip-shaped semiconductor element.

Alternatively, the protrusions may be provided at different densities according to positions in the region in the region where the protrusions are arranged on the surface of the chip-shaped semiconductor element.

In this case, a gap between the adjacent protrusions may be provided across the region where the protrusions are arranged. Alternatively, the density of the protrusions in a central region of the surface of the chip-shaped semiconductor element may be higher than the density of the protrusions in a peripheral region surrounding the central region.

In the chip-shaped semiconductor element of the present disclosure having the various preferable configurations described above, the protrusions of the same shape may be provided on the surface of the chip-shaped semiconductor element.

Alternatively, a plurality of types of protrusions having different shapes may be provided on the surface of the chip-shaped semiconductor element. In this case, a plurality of types of protrusions of different heights may be provided.

In the chip-shaped semiconductor element of the present disclosure having the various preferable configurations described above, the protrusion may be formed so as to be smaller in shape with a distance from the surface of the chip-shaped semiconductor element. For example, the protrusion may have a shape of a truncated cone with a surface on a side of the chip-shaped semiconductor element as a bottom surface and a cross-sectional shape becoming smaller with a distance from the surface of the chip-shaped semiconductor element. In the chip-shaped semiconductor element of the present disclosure having the various preferable configurations described above, the protrusion may have a symmetrical shape or an asymmetrical shape.

A shape and a configuration of the wiring board used in the semiconductor device, the chip-shaped semiconductor element, the electronic device provided with the semiconductor device, and the method of manufacturing the semiconductor device according to the present disclosure including the above-described various preferable configurations (they are hereinafter sometimes simply referred to as the present disclosure) are not especially limited as long as there is no obstacle in implementing the present disclosure. For example, one chip-shaped semiconductor element may be mounted on one wiring board, or a plurality of chip-shaped semiconductor elements may be mounted on one wiring board. Furthermore, the chip-shaped semiconductor element and a surface mounting component may be arranged.

The protrusion provided on the chip-shaped semiconductor element of the present disclosure may be formed by using a photolithography technique such as exposure by using a PI-, phenol-, PBO-, BCB-, or acryl-based photosensitive resin, for example. Alternatively, this may also be formed by using a 3D printer technology by using polyamide- or ABS-based resin. Moreover, this may also be formed by etching by using a glass-based material.

The method of applying the underfilling material to the wiring board is not especially limited as long as there is no obstacle in implementing the present disclosure. For example, this may be applied by various printing methods such as a spin coating method, a spray coating method, and a printing method.

A material of the underfilling material to be used in the present disclosure is not especially limited as long as there is no obstacle in implementing the present disclosure. Specifically, any material viscosity of which decreases to such an extent that self-alignment is not inhibited at the time of the reflow treatment on which cure treatment may be performed after the reflow treatment may be used. As the material of the underfilling material, an epoxy-based material may be illustrated, for example. For example, a thermal curing underfilling material is cured by reaction of a curing agent by long-time heating. A heating time at the time of reflow is short, the curing reaction is slight, and the viscosity decreases with an increase in temperature.

Various conditions in this specification are satisfied not only in a case where they are strictly established but also in a case where they are substantially established. Existence of various variations caused by design or manufacturing is allowed. Furthermore, the drawings used in the following description are schematic and do not illustrate actual dimensions or ratios.

### First Embodiment

A first embodiment relates to a semiconductor device, a chip-shaped semiconductor element, and a method of manufacturing a semiconductor device according to a first aspect of the present disclosure.

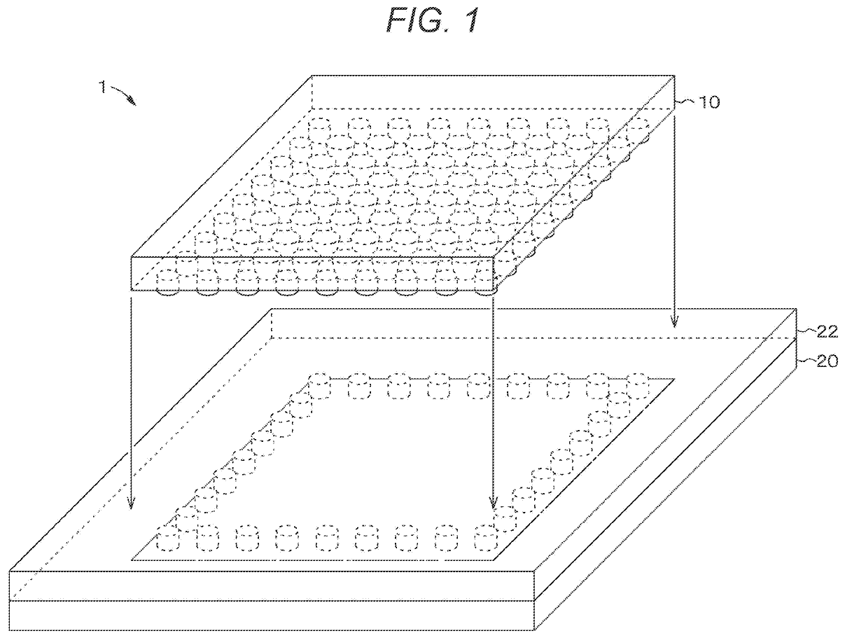

FIG. 1 is a schematic exploded perspective view for explaining the semiconductor device according to the first aspect of the present disclosure.

Note that, for convenience of illustration and explanation, in FIG. 1, electrodes, protrusions and the like provided on a chip-shaped semiconductor element 10 and a wiring board 20 are exaggeratedly illustrated. Furthermore, for convenience of explanation, although it is described that one chip-shaped semiconductor element is mounted on one wiring board, the present disclosure is not limited to this.

A semiconductor device 1 is provided with the wiring board 20 and the chip-shaped semiconductor element 10 flip-chip mounted on the wiring board 20. A plurality of solder bumps and a plurality of protrusions including an insulating material are provided on a surface of the chip-shaped semiconductor element 10 on a side facing the wiring board 20.

The chip-shaped semiconductor element 10 is arranged so as to face the wiring board 20 via an underfilling material 22 in a state in which the underfilling material 22 having a characteristic that viscosity decreases with an increase in temperature is applied to the wiring board 20, and is thereafter subjected to reflow treatment, so that this is flip-chip mounted on the wiring board 20.

The chip-shaped semiconductor element 10 includes a protrusion formed so that a tip end thereof does not reach the wiring board 20 in a state in which the chip-shaped semiconductor element 10 is flip-chip mounted. Then, the chip-shaped semiconductor element 10 is mounted in a state positioned with respect to the wiring board 20 by fusion of a solder bump provided on the wiring board 20 with a solder bump provided on the chip-shaped semiconductor element 10 by the reflow treatment.

A basic manufacturing process of the semiconductor device 1 is described.

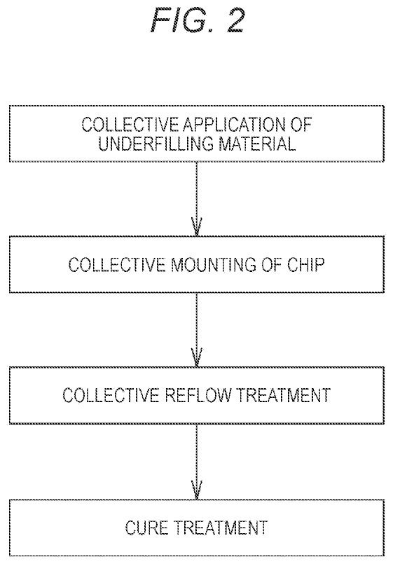

FIG. 2 is a process chart for explaining the basic manufacturing process of the semiconductor device according to the first aspect of the present disclosure.

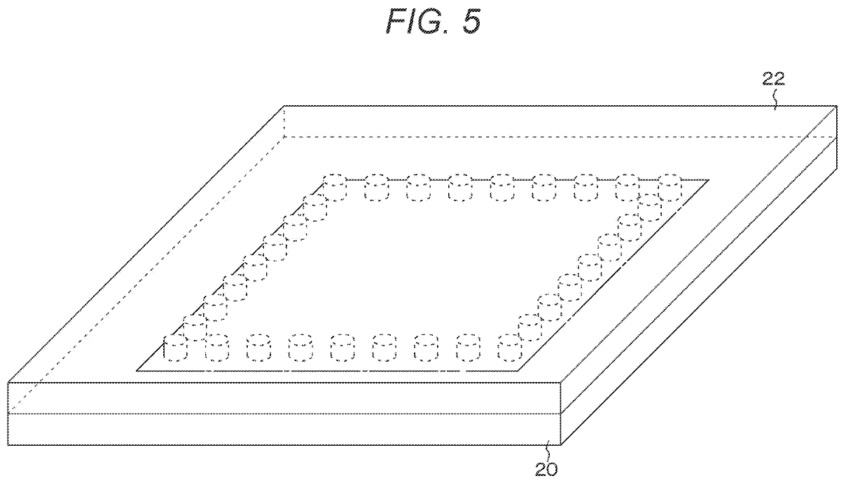

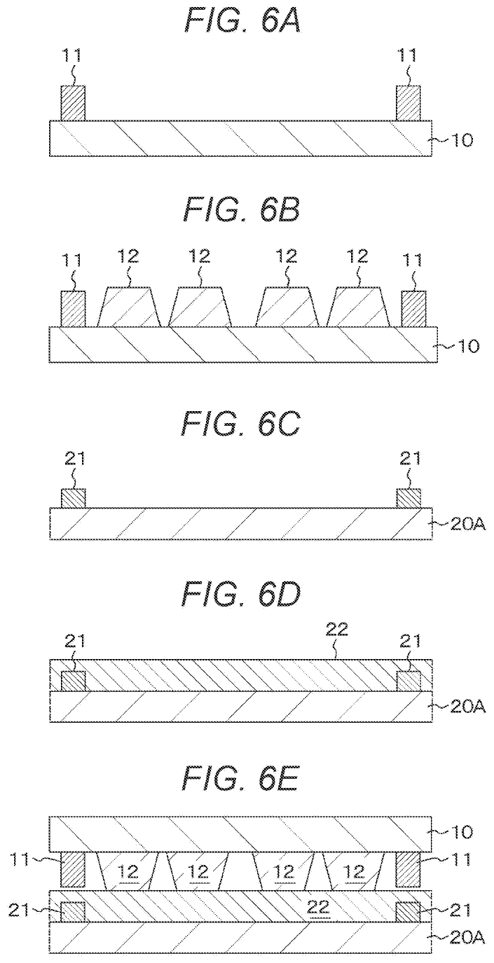

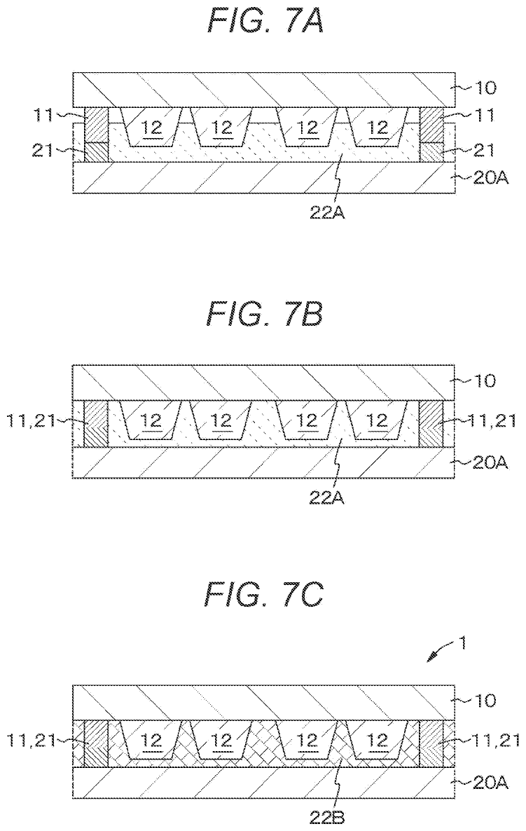

As illustrated in FIG. 2, the underfilling material 22 is collectively applied to the wiring board 20 (for example, refer to FIG. 5 as described later). The chip-shaped semiconductor element 10 is arranged so as to face the wiring board 20 via the underfilling material 22. Note that, at that time, it is sufficient that the chip-shaped semiconductor element 10 is arranged with such accuracy that self-alignment may be performed. In other words, positioning with high accuracy such that electrodes of the wiring board 20 and the chip-shaped semiconductor element 10 correctly face each other is not required. Next, collective reflow treatment is performed. As is to be described later in detail with reference to FIGS. 6 and 7 as described later, the self-alignment by solder joint occurs during the reflow treatment, and the chip-shaped semiconductor element 10 is mounted in a state of being positioned with respect to the wiring board 20. Thereafter, cure treatment is performed on the underfilling material 22 and the semiconductor device 1 is completed.

As described above, a plurality of solder bumps and a plurality of protrusions including the insulating material are provided on the surface of the chip-shaped semiconductor element 10 on the side facing the wiring board 20. The chip-shaped semiconductor element 10 before the flip-chip mounting is to be described in detail.

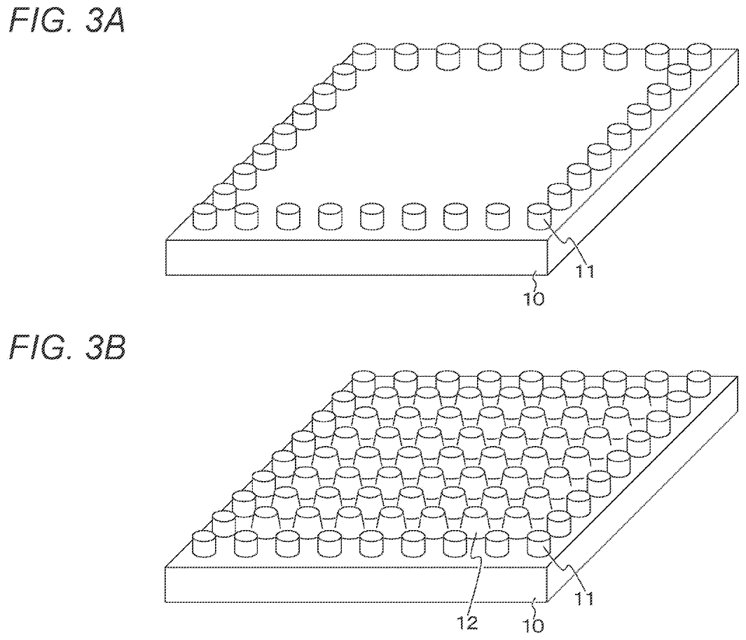

FIGS. 3A and 3B are schematic perspective views for explaining arrangement of the electrodes and protrusions of the chip-shaped semiconductor element 10. FIG. 3A illustrates a state before the protrusions are formed, and FIG. 3B illustrates a state after the protrusions are formed.

In the example illustrated in the drawing, solder bumps 11 are provided at predetermined intervals along each side of the rectangular chip-shaped semiconductor element 10 (refer to FIG. 3A). On the chip-shaped semiconductor element 10 in this state, a plurality of protrusions 12 including the insulating material is formed inside a region surrounded by the solder bumps 11 using, for example, a photolithography technique (refer to FIG. 3B).

In the example illustrated in the drawing, the protrusion 12 is formed so as to be smaller in shape with a distance from the surface of the chip-shaped semiconductor element 10 and has a symmetrical shape. The protrusion 12 has a function of absorbing the underfilling material 22 previously applied to the wiring board 20 to a side of the chip-shaped semiconductor element by capillary action to fill the same. The protrusion 12 is formed to be higher than the solder bump 11.

Next, the wiring board 20 before the flip-chip mounting is described.

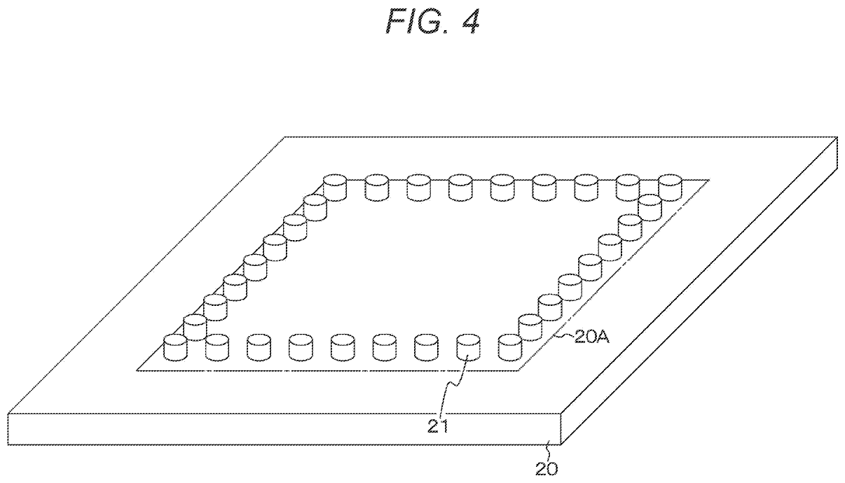

FIG. 4 is a schematic perspective view for explaining an electrode arrangement of the wiring board. FIG. 5 is a schematic perspective view for explaining an arrangement of the electrodes of the wiring board and a previously applied underfilling material layer.

A portion facing the chip-shaped semiconductor element 10 of the wiring board 20 is represented by reference sign 20A. Note that, in the following description, the portion represented by reference sign 20A is sometimes simply referred to as a facing portion 20A. The facing portion 20A is substantially rectangular on which solder bumps 21 are formed along each side so as to correspond to the chip-shaped semiconductor element 10 (refer to FIG. 4). The underfilling material 22 is collectively applied to the wiring board 20 in this state (refer to FIG. 5).

An outline of the semiconductor device 1 is described above. Subsequently, the method of manufacturing the semiconductor device 1 is described in detail with reference to the drawings.

The method of manufacturing the semiconductor device of the present disclosure includes

a process of arranging the chip-shaped semiconductor element 10 provided with a plurality of solder bumps 11 and a plurality of protrusions 12 including the insulating material on the surface on the side facing the wiring board 20 so as to face the wiring board 20 via the underfilling material 22 in a state in which the underfilling material 22 having a characteristic that viscosity decreases with an increase in temperature is applied to the wiring board 20, and thereafter applying reflow treatment to flip-chip mount the same on the wiring board 20.

FIGS. 6A to 6E are schematic partial cross-sectional views for explaining the process of manufacturing the semiconductor device. FIGS. 7A to 7C are schematic partial cross-sectional views for explaining the process of manufacturing the semiconductor device following FIG. 6E. For the convenience of illustration, in the drawings, only a part of the facing portion 20A is illustrated as the wiring board. Furthermore, a shape of each component and the like is illustrated in a simplified manner.

[Process-100] (Refer to FIGS. 6A and 6B)

The chip-shaped semiconductor element 10 is prepared, and the solder bumps 11 to be the electrodes are formed thereon (refer to FIG. 6A). Next, a plurality of protrusions 12 including the insulating material is formed inside the region surrounded by the solder bumps 11 using, for example, the photolithography technique (refer to FIG. 6B).

[Process-110] (Refer to FIGS. 6C and 6D)

The wiring board 20 is prepared, and the solder bumps 21 to be the electrodes are formed on the facing portion 20A (refer to FIG. 6C). Next, the underfilling material 22 is collectively applied to an entire surface including the facing portion 20A (refer to FIG. 6D).

As described above, the underfilling material 22 is collectively applied to the wiring board 20. It is not necessary to selectively apply the same to the facing portion 20A. Furthermore, the underfilling material 22 which has a flux function is used in application.

[Process-120] (Refer to FIG. 6E)

Thereafter, the chip-shaped semiconductor element 10 is arranged so as to face the wiring board 20 via the underfilling material 22.

[Process-130] (Refer to FIGS. 7A and 7B)

Next, the reflow treatment is performed.

When the viscosity of the underfilling material 22 decreases with the increase in temperature, the protrusion 12 of the chip-shaped semiconductor element 10 absorbs the underfilling material 22 by capillary action (refer to FIG. 7A). The underfilling material in a flowing state is represented by reference sign 22A.

Subsequently, the solder bumps 11 and 21 of the chip-shaped semiconductor element 10 and the wiring board 20 fuse to attract each other (refer to FIG. 7B). As a result, the self-alignment occurs, and the chip-shaped semiconductor element 10 is positioned with respect to the wiring board 20. Therefore, even if a slight deviation remains in the arrangement of the chip-shaped semiconductor element 10 in [process-120], no trouble occurs in the positioning.

Furthermore, since the chip-shaped semiconductor element 10 further sinks by the fusion of the solder bumps 11 and 21, filling of the underfilling material 22A between the chip-shaped semiconductor element 10 and the wiring board 20 is promoted. A clearance between the protrusions of the chip-shaped semiconductor element 10 becomes a gas flow path in a filling process of the underfilling material 22A. Therefore, voids of the underfilling material 22 at the time of chip mounting may be reduced. An absorption amount and a reaching height of the underfilling material 22A in the reflow treatment may be controlled by a design of the protrusion 12.

If the tip end of the protrusion 12 reaches the wiring board 20 in the filling process of the underfilling material 22A, a self-alignment effect due to the fusion of the solder bumps 11 and 21 is inhibited. Therefore, the protrusion 12 is formed so that the tip end does not reach the wiring board 20 in the state in which the chip-shaped semiconductor element 10 is flip-chip mounted. Note that, in some cases, a protrusion for setting a gap interval and the like a tip end of which reaches the wiring board 20 may be further included in a range in which the self-alignment effect is not inhibited.

[Process-140] (Refer to FIG. 7C)

Next, the cure treatment of the underfilling material 22A is performed. As the cure treatment, a preferred method may be appropriately selected according to a type of the underfilling material. The underfilling material after curing is represented by reference sign 22B. As a result, the semiconductor device 1 in which the chip-shaped semiconductor element 10 is mounted on the wiring board 20 may be obtained.

The manufacturing method of the present disclosure is a method of previously applying the underfilling material, and a takt time required for sealing is shorter than that in a capillary underfilling system. Moreover, in the manufacturing method of the present disclosure, it is not necessary to apply pressure and heat to individual chips when mounting the chips. Then, since the self-alignment by solder joint is exhibited, accuracy of positioning at the time of arranging the chip-shaped semiconductor element is relaxed. Therefore, according to the manufacturing method of the present disclosure, the process may be simplified, and the takt time and a lead time may be significantly shortened.

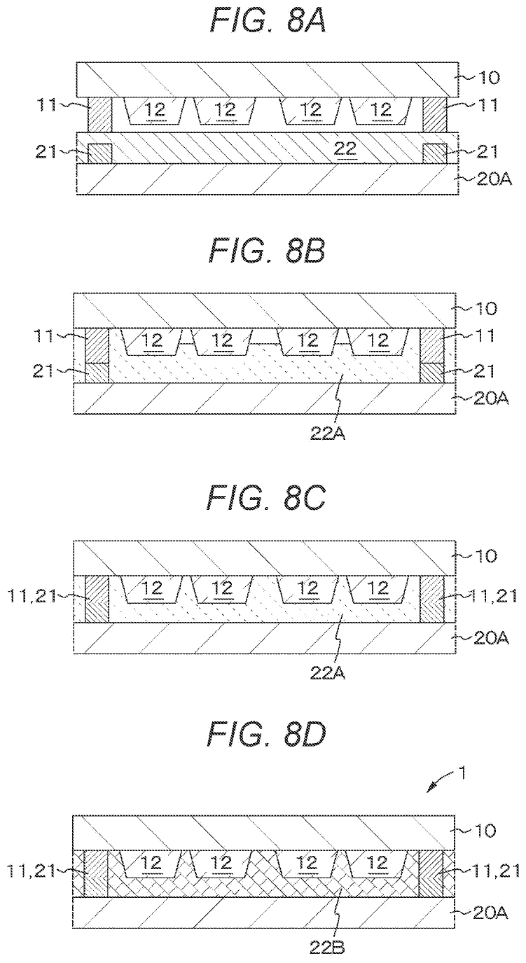

Note that, although the protrusion 12 is formed to be higher than the solder bump 11 in the description above, the present invention is not limited to this. For example, the protrusion 12 may be as high as the solder bump 11, or the protrusion 12 may be lower than the solder bump 11. A process chart in a case where the protrusion 12 is made lower than the solder bump 11 is illustrated in FIG. 8.

FIG. 8A corresponds to FIG. 6E. Since the protrusion 12 is lower than the solder bump 11, the solder bump 11 is brought into contact with the underfilling material 22 earlier than the protrusion 12.

FIG. 8B corresponds to FIG. 7A, and FIG. 8C corresponds to FIG. 7B. When the viscosity of the underfilling material 22 decreases by the reflow treatment, the resin is first absorbed through the solder bump 11 (refer to FIG. 8B), and then the resin is also absorbed by the protruding portion 12 (refer to FIG. 8C).

FIG. 8D corresponds to FIG. 7C. By performing the cure treatment after the reflow treatment, the semiconductor device 1 in which the chip-shaped semiconductor element 10 is mounted on the wiring board 20 may be obtained.

### Second Embodiment

A second embodiment relates to a chip-shaped semiconductor element according to a first aspect of the present disclosure.

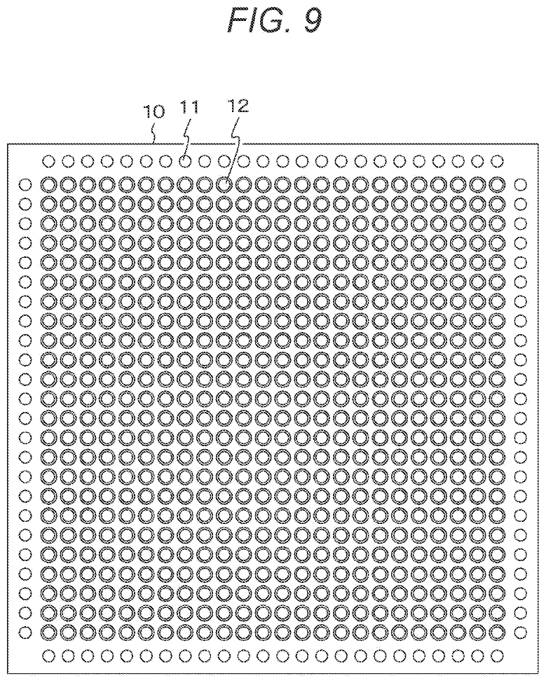

FIG. 9 is a schematic plan view for explaining a structure of the chip-shaped semiconductor element according to the second embodiment.

In a chip-shaped semiconductor element 10 according to the second embodiment, solder bumps 11 are arranged continuously along each side of an outer periphery of the chip-shaped semiconductor element 10. Then, protrusions 12 are provided at a constant density in a region where the protrusions are arranged on a surface of the chip-shaped semiconductor element 10 (more specifically, a region surrounded by the solder bumps).

In this configuration, the protrusions 12 of the same shape are uniformly arranged at the same pitch on the surface of the chip-shaped semiconductor element 10. The protrusions 12 may be formed by using, for example, a photolithography technique in which a photosensitive insulating resin material is applied and then exposed using a photomask on which a necessary pattern is drawn, and thereafter a developing process is performed.

### Third Embodiment

A third embodiment also relates to a chip-shaped semiconductor element according to a first aspect of the present disclosure. In the second embodiment, the protrusions are provided at the constant density in the region where the protrusions are arranged. On the other hand, in the third embodiment, protrusions are provided at different densities depending on positions in a region.

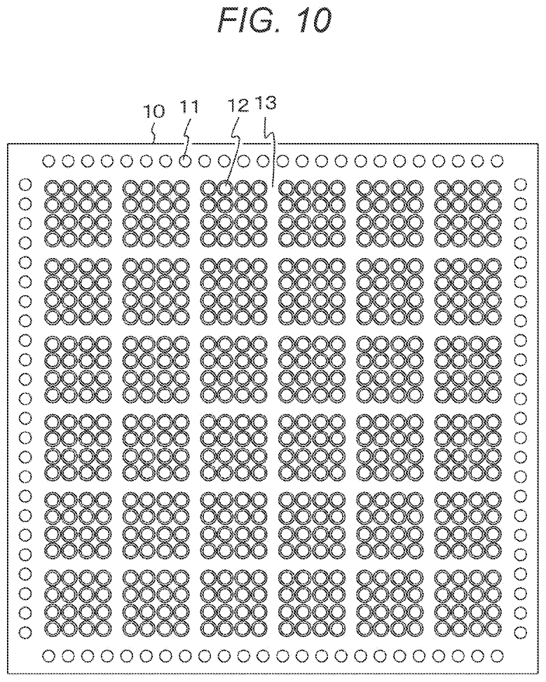

FIG. 10 is a schematic plan view for explaining a structure of the chip-shaped semiconductor element according to the third embodiment.

In the third embodiment also, solder bumps 11 are arranged continuously along each side of an outer periphery of a chip-shaped semiconductor element 10, and protrusions 12 are provided in a region where the protrusions are arranged on a surface of the chip-shaped semiconductor element 10.

However, in the third embodiment, the region surrounded by the solder bumps 11 is divided into a plurality of blocks. Then, a gap 13 is provided between the blocks. In each block, the protrusions 12 of the same shape are uniformly arranged at the same pitch. The gap 13 is set to be wider than a gap between the protrusions in the block. In this structure, the gap 13 between the adjacent protrusions is arranged across the region where the protrusions are arranged. The gaps 13 serve as gas flow paths when the chip-shaped semiconductor element 10 is mounted, so that voids of an underfilling material may be efficiently reduced when the chip-shaped semiconductor element 10 is mounted.

### Fourth Embodiment

A fourth embodiment is a variation of the third embodiment. In the third embodiment, the protrusions of the same shape are arranged uniformly at the same pitch in each block. The fourth embodiment is principally different from this arrangement in that a plurality of types of protrusions having different shapes is provided.

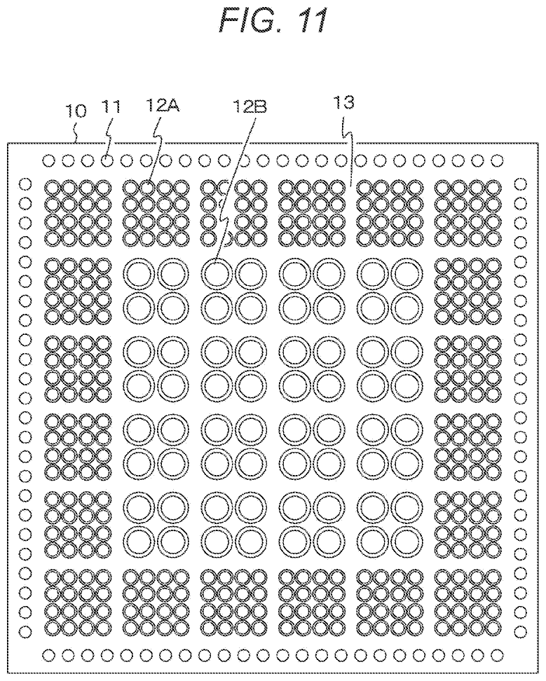

FIG. 11 is a schematic plan view for explaining a structure of a chip-shaped semiconductor element according to the fourth embodiment.

In the fourth embodiment also, solder bumps 11 are continuously arranged along each side of an outer periphery of a chip-shaped semiconductor element 10, and the protrusions are provided in a region where the protrusions are arranged on a surface of the chip-shaped semiconductor element 10. Then, the region surrounded by the solder bumps 11 is divided into a plurality of blocks. Then, a gap 13 is provided between the blocks.

In the block near a periphery of the chip-shaped semiconductor element 10, for example, a protrusion 12A similar to a protrusion 12 illustrated in FIG. 10 is arranged. On the other hand, in the block near the center of the chip-shaped semiconductor element 10, a protrusion 12B having a larger diameter is arranged. The protrusion 12B also is formed to be smaller in shape with a distance from a surface of the chip-shaped semiconductor element 10 and is symmetrical. Note that the protrusion 12A and the protrusion 12B may be at the same height or different heights.

As in the third embodiment, the gap 13 is set to be wider than a gap between the protrusions in the block. As in the third embodiment, since the gaps 13 serve as gas flow paths when the chip-shaped semiconductor element is mounted, voids of an underfilling material when the chip-shaped semiconductor element is mounted may be efficiently reduced.

### Fifth Embodiment

A fifth embodiment also relates to a chip-shaped semiconductor element according to a first aspect of the present disclosure.

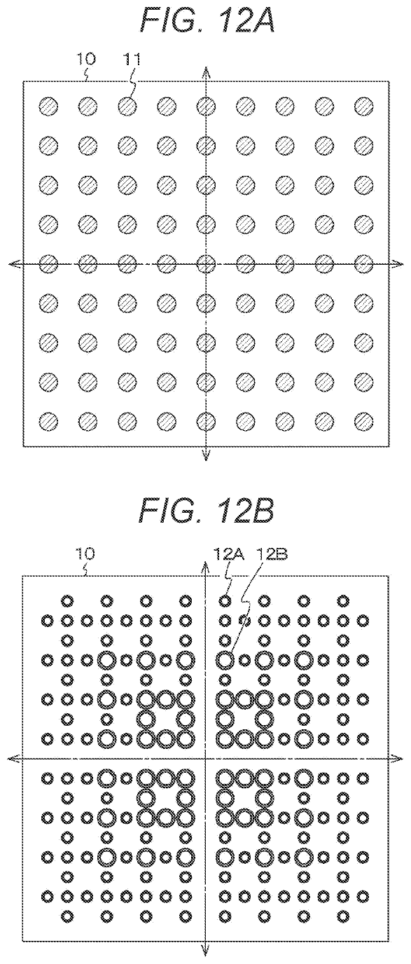

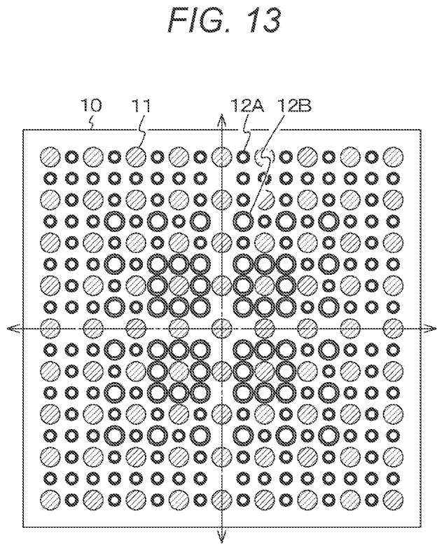

FIGS. 12A and 12B are schematic plan views for explaining a structure of the chip-shaped semiconductor element according to the fifth embodiment, in which FIG. 12A illustrates an arrangement relationship of electrodes and FIG. 12B illustrates an arrangement relationship of protrusions. FIG. 13 is a schematic plan view for explaining the structure of the chip-shaped semiconductor element according to the fifth embodiment, illustrating an arrangement relationship of the electrodes and protrusions.

In the second to fourth embodiments, the solder bumps are arranged continuously along each side of the outer periphery of the chip-shaped semiconductor element. On the other hand, in the fifth embodiment, solder bumps 11 are arranged in a matrix pattern on a surface of a chip-shaped semiconductor element 10. Then, the protrusions are arranged so as to fill a space between the solder bumps in a region where the protrusions are arranged on a surface of the chip-shaped semiconductor element 10 (more specifically, a region where the solder bumps are not arranged).

In the region where the protrusions are arranged on the surface of the chip-shaped semiconductor element 10, the protrusions are provided at different densities depending on positions in the region. Then, a plurality of types of protrusions having different shapes are provided on the surface of the chip-shaped semiconductor element 10, and the density of the protrusions in a central region of the surface of the chip-shaped semiconductor element 10 is higher than the density of the protrusions in a peripheral region surrounding the central region.

In the example illustrated in the drawing, the surface of the chip-shaped semiconductor element 10 is divided into four blocks. Then, basically, it is configured such that large-sized protrusions 12B are arranged at a high density in a region near the center of the chip-shaped semiconductor element 10, and small-sized protrusions 12A are arranged at a low density with a distance from the center of the chip-shaped semiconductor element 10.

### Sixth Embodiment

A sixth embodiment is a variation of the fifth embodiment. In the fifth embodiment, the solder bumps are arranged in the matrix pattern on the surface of the chip-shaped semiconductor element. The sixth embodiment is different from this arrangement in that solder bumps are not arranged partially, and protrusions are formed instead.

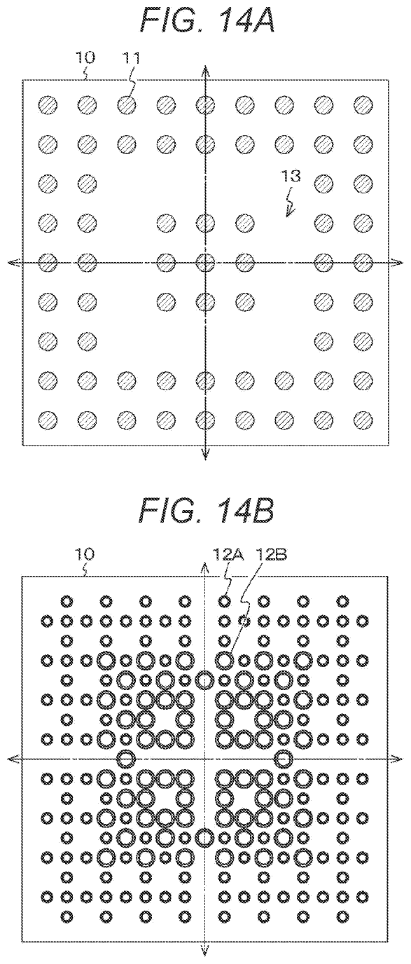

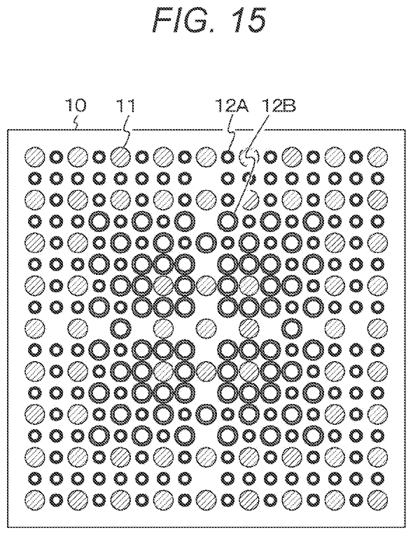

FIGS. 14A and 14B are schematic plan views for explaining a structure of a chip-shaped semiconductor element according to the sixth embodiment, in which FIG. 14A illustrates an arrangement relationship of electrodes and FIG. 14B illustrates an arrangement relationship of protrusions. FIG. 15 is a schematic plan view for explaining the structure of the chip-shaped semiconductor element according to the sixth embodiment, illustrating an arrangement relationship of the electrodes and protrusions.

In the sixth embodiment, solder bumps 11 are not arranged in a region represented by reference sign 13. Protrusions 12A and 12B are arranged so as to fill the region 13.

### Seventh Embodiment

A seventh embodiment is a variation of the sixth embodiment.

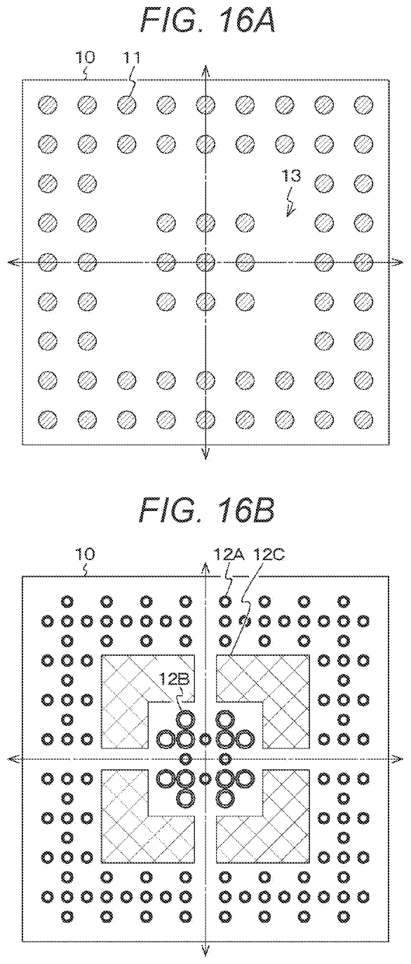

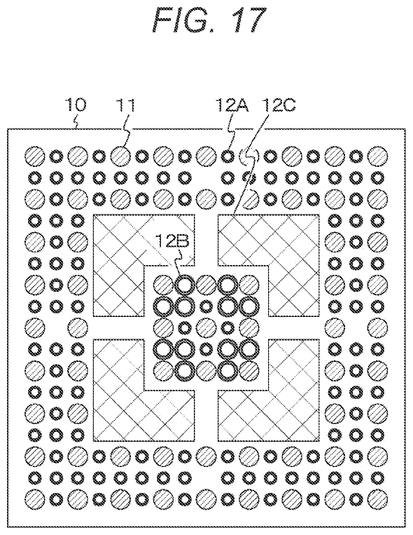

FIGS. 16A and 16B are schematic plan views for explaining a structure of a chip-shaped semiconductor element according to the seventh embodiment, in which FIG. 16A illustrates an arrangement relationship of electrodes and FIG. 16B illustrates an arrangement relationship of protrusions. FIG. 17 is a schematic plan view for explaining the structure of the chip-shaped semiconductor element according to the seventh embodiment, illustrating an arrangement relationship of the electrodes and protrusions.

In the seventh embodiment, in a region 13 where solder bump 11 are not arranged, a protrusion 12C formed to conform to a planar shape is formed.

### Eighth Embodiment

An eighth embodiment also relates to a chip-shaped semiconductor element according to a first aspect of the present disclosure.

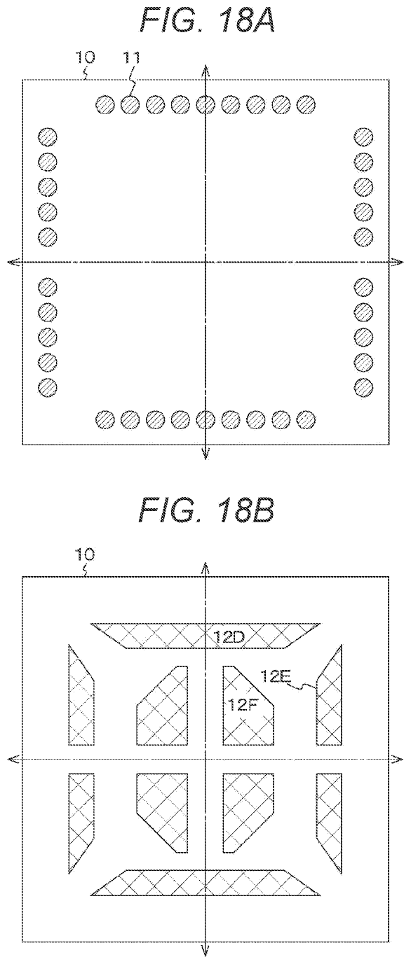

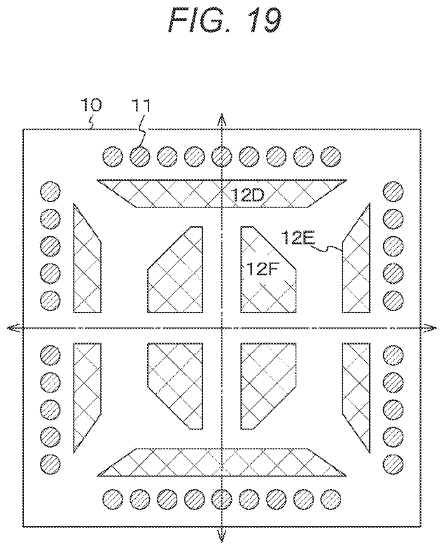

FIGS. 18A and 18B are schematic plan views for explaining a structure of the chip-shaped semiconductor element according to the eighth embodiment, in which FIG. 18A illustrates an arrangement relationship of electrodes and FIG. 18B illustrates an arrangement relationship of protrusions. FIG. 19 is a schematic plan view for explaining the structure of the chip-shaped semiconductor element according to the eighth embodiment, illustrating an arrangement relationship of the electrodes and protrusions.

In the first embodiment, the process in a case where the protrusion is lower than the solder bump is described with reference to FIGS. 8A to 8D. In this case, since the solder bump is brought into contact with the underfilling material earlier than the protrusion, it is preferable to arrange the solder bump or the like so as to secure a passage leading to the outside of the chip.

In a chip-shaped semiconductor element 10 according to the eighth embodiment, solder bumps 11 are arranged along each side of an outer periphery of the chip-shaped semiconductor element 10. However, in order to secure passages leading to the outside of the chip at four corners and central portions of right and left sides of the chip-shaped semiconductor element 10, the solder bumps 11 are arranged at intervals in these portions.

Then, protrusions 12C, 12D, and 12E are arranged so as to secure the flow paths leading to the outside of the chip in a region where the protrusions are arranged on a surface of the chip-shaped semiconductor element 10 (more specifically, the region surrounded by the solder bumps).

According to this configuration, even if the solder bump 11 is brought into contact with an underfilling material 22 earlier at the time of reflow, the passage leading from the center of the chip-shaped semiconductor element 10 to the outside of the chip is secured, so that voids may be efficiently decreased.

### Ninth Embodiment

A ninth embodiment relates to a semiconductor device and a chip-shaped semiconductor element according to a first aspect of the present disclosure.

In the first embodiment, it is described that the semiconductor device is formed by mounting one chip-shaped semiconductor element on the wiring board. On the other hand, the semiconductor device of the ninth embodiment has a so-called multi-chip configuration.

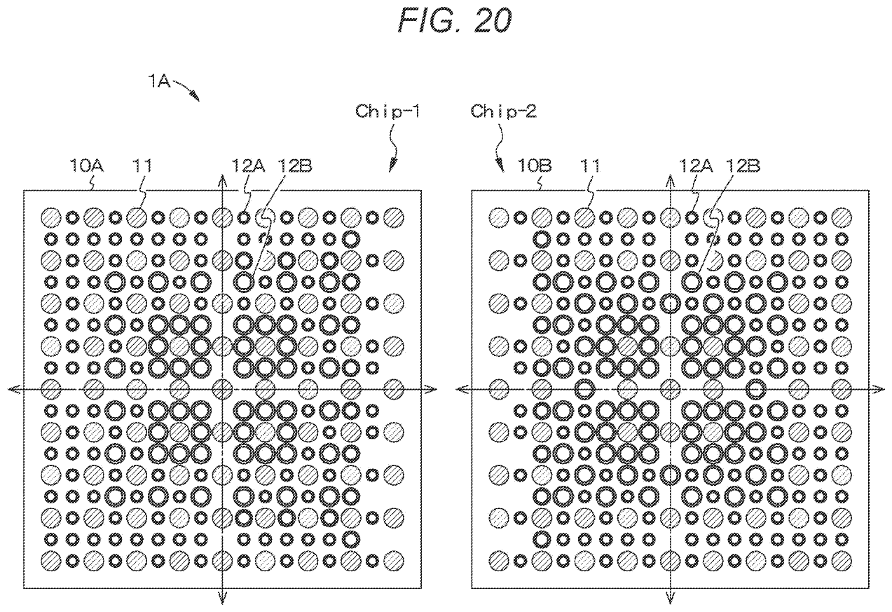

FIG. 20 is a schematic plan view for explaining a structure of the semiconductor device according to the ninth embodiment provided with a pair of chip-shaped semiconductor elements.

A semiconductor device 1A according to the ninth embodiment is a semiconductor device having a multi-chip configuration formed by mounting chip-shaped semiconductor elements 10A and 10B on a wiring board. Note that, in FIG. 20, the wiring board is not illustrated.

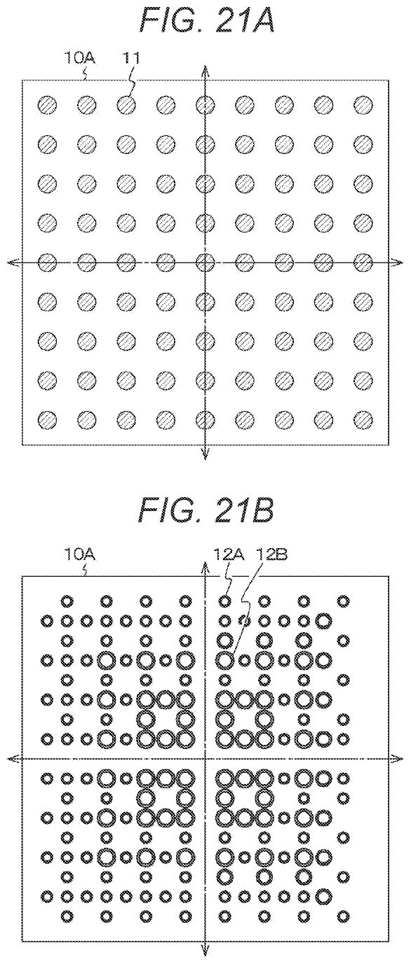

FIGS. 21A and 21B are schematic plan views for explaining a structure of one of the pair of chip-shaped semiconductor elements according to the ninth embodiment, in which FIG. 21A illustrates an arrangement relationship of electrodes and FIG. 21B illustrates an arrangement relationship of protrusions.

In one chip-shaped semiconductor element 10A, as in the fifth embodiment, solder bumps 11 are arranged in a matrix pattern on a surface of the chip-shaped semiconductor element 10A. Then, protrusions 12A and 12B are arranged so as to fill a space between the solder bumps in a region where the protrusions are arranged on the surface of the chip-shaped semiconductor element 10A (more specifically, the region on which the solder bumps are not arranged).

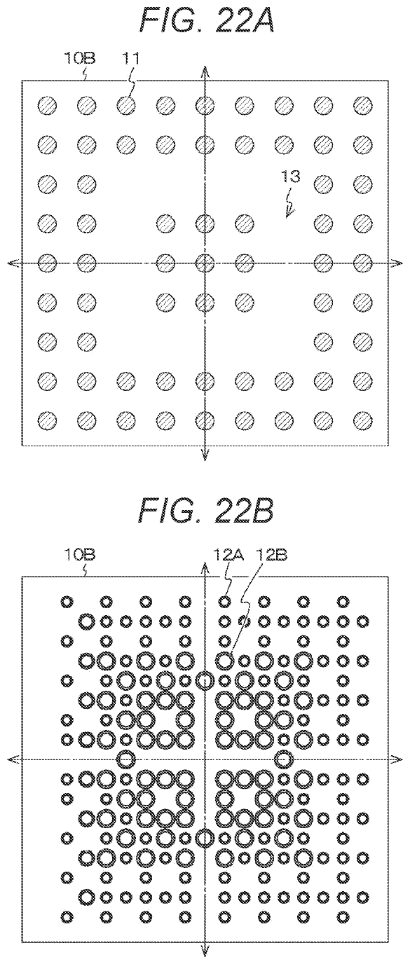

FIGS. 22A and 22B are schematic plan views for explaining a structure of the other of the pair of chip-shaped semiconductor elements according to the ninth embodiment, in which FIG. 22A illustrates an arrangement relationship of electrodes and FIG. 22B illustrates an arrangement relationship of protrusions.

In the other chip-shaped semiconductor element 10B, as in the sixth embodiment, the solder bumps 11 are not arranged partially, and protrusions are formed instead.

In any one of the chip-shaped semiconductor elements 10A and 10B, the surface of the chip-shaped semiconductor element is divided into four blocks. Then, a size and density of the protrusions in a region near the center of each chip-shaped semiconductor element are increased, and the size and density thereof are decreased toward an outer side. Moreover, on a side on which the chip-shaped semiconductor elements 10A and 10B face each other, the size and density of the protrusions are made smaller and lower than those on the other sides. By decreasing the density of the protrusions, it is possible to prevent an excessive inflow of an underfilling material on the surface on which the chip-shaped semiconductor elements 10A and 10B face each other, and tension generated between the chip-shaped semiconductor elements may be controlled properly.

### Tenth Embodiment

A tenth embodiment relates to a semiconductor device according to a first aspect of the present disclosure.

The semiconductor device according to the tenth embodiment is a semiconductor device in which wire connection by flip-chip mounting and wire connection by wire bonding are mixed.

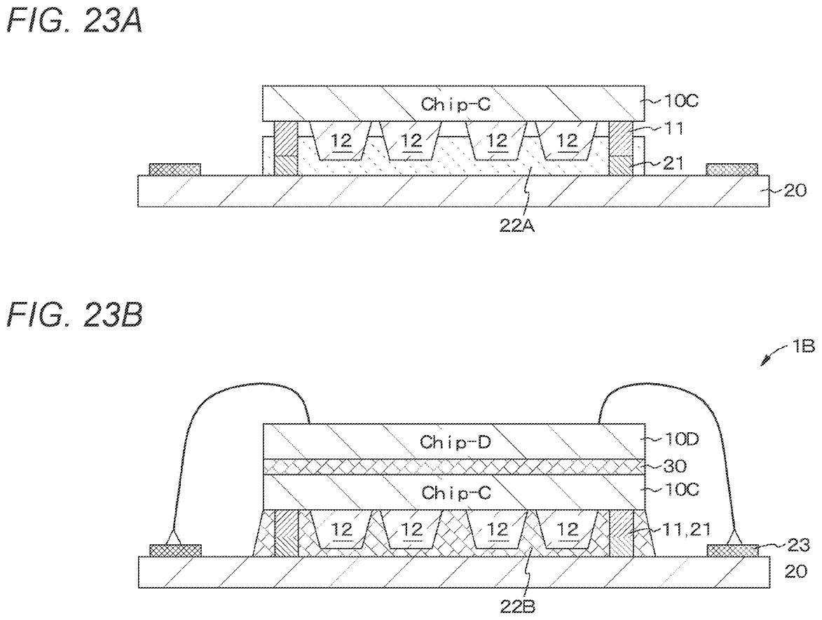

FIGS. 23A and 23B are schematic partial cross-sectional views for explaining a process of manufacturing the semiconductor device according to the tenth embodiment.

Collective application of an underfilling material is an obstacle in wire bonding. Therefore, an underfilling material 22 is selectively applied to a wiring board 20 in a portion corresponding to a chip-shaped semiconductor element 10C to be flip-chip mounted. Then, after a chip-shaped semiconductor element 10D is arranged thereon, reflow treatment and then cure treatment are performed. FIG. 23A illustrates a state during the reflow treatment.

Next, after mounting the chip-shaped semiconductor element 10D to be wire bonded by, for example, a bonding layer 30 on the chip-shaped semiconductor element 10C which is flip-chip mounted, an electrode 23 is wired by wire bonding 40, so that a semiconductor device 1B may be obtained (refer to FIG. 23B).

### Eleventh Embodiment

An eleventh embodiment relates to a chip-shaped semiconductor element according to a first aspect of the present disclosure.

In a case where a protrusion provided on the chip-shaped semiconductor element has a symmetrical shape, when the protrusion sinks into a softened underfilling material, the underfilling material is basically pushed out isotropically around the protrusion.

In a case where a filling property of the underfilling material is not uniform, it is conceivable to make a shape of the protrusion asymmetric as well as to adjust an arrangement density of the protrusions on a surface of the chip-shaped semiconductor element.

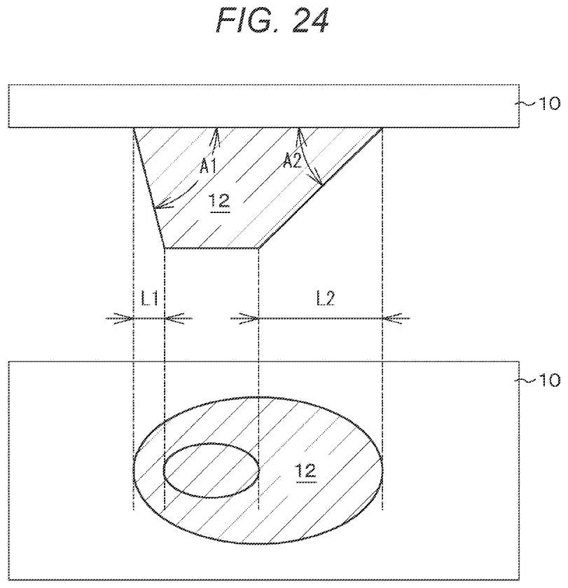

FIG. 24 is a schematic diagram for explaining a structure of a protruding portion of the chip-shaped semiconductor element according to the tenth embodiment.

A protruding portion 12 illustrated in the drawing has an asymmetrical shape such that an angle formed by a left slope (represented by reference sign A1) and an angle formed by a right slope (represented by reference sign A2) with respect to the chip-shaped semiconductor element surface are different and central positions are different between a surface of a tip end of the protrusion 12 and a surface on a side of the chip-shaped semiconductor element.

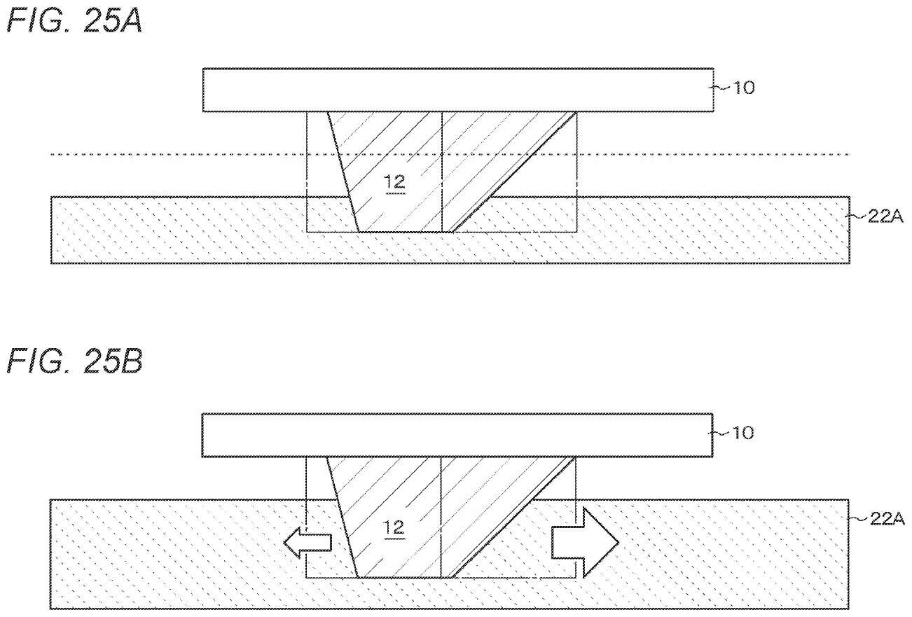

FIGS. 25A and 25B are schematic diagrams for explaining a function of the protruding portion of the chip-shaped semiconductor element according to the eleventh embodiment.

When the chip-shaped semiconductor element further sinks from a state illustrated in FIG. 25A to reach a state illustrated in FIG. 25B, an underfilling material 22A in a flowing state is pushed out more to the right of the protrusion 12. By this, a degree of filling of the underfilling material 22 may be adjusted.

A preferred shape may be appropriately selected as the asymmetrical shape of the protrusion 12 on the basis of the specifications of the chip-shaped semiconductor element and the like. The asymmetrical protrusion may be formed using, for example, a 3D printer technology and the like.

### Twelfth Embodiment

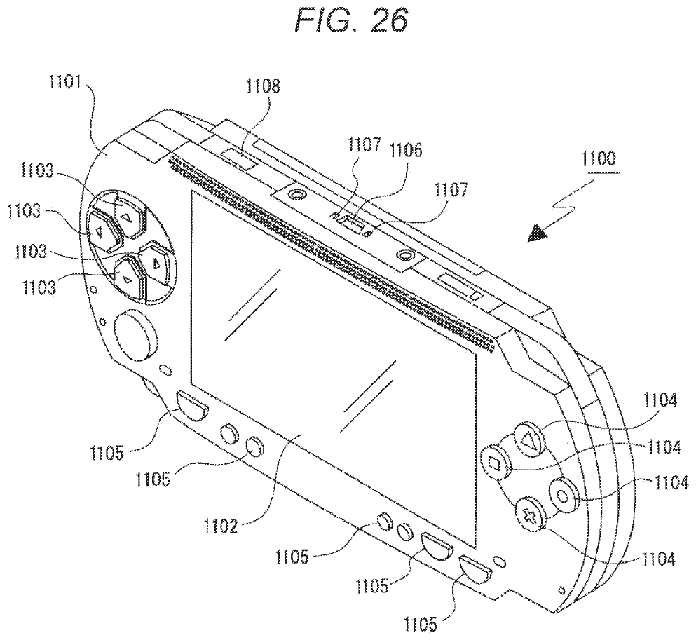

A twelfth embodiment according to the present disclosure is an electronic device on which the semiconductor device obtained by the embodiments described above is mounted. A schematic configuration of the electronic device is illustrated in FIG. 26.

An electronic device 1100 in which required units are arranged inside and outside an outer casing 1101 formed into a horizontally long flat shape, for example, is used as a game device, for example.

A display panel 1102 is provided at the center in a right-to-left direction on a front surface of the outer casing 1101, and four operation keys 1103 and four operations keys 1104 arranged so as to be spaced apart in a circumferential direction are provided on the left and right of the display panel 1102. Furthermore, four operation keys 1105 are provided at a lower end of the front surface of the outer casing 1101. The operation keys 1103, 1104, and 1105 serve as direction keys and an enter key are used to select menu items displayed on the display panel 1102, to advance a game and the like.

A connection terminal 1106 for connecting an external device, a supply terminal 1107 for power supply, a light receiving window 1108 for performing infrared communication with the external device and the like are provided on an upper surface of the outer casing 1101.

Subsequently, a circuit configuration of the electronic device 1100 is described.

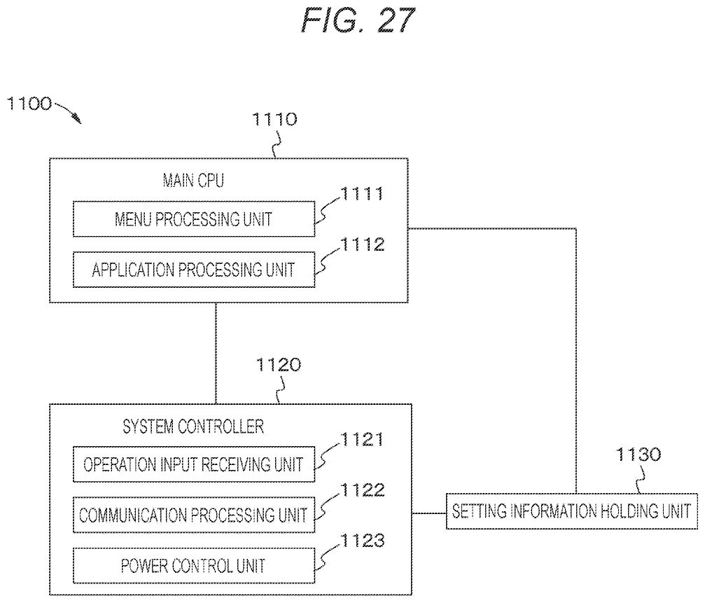

FIG. 27 is a schematic block diagram illustrating the circuit configuration of the electronic device illustrated in FIG. 26.

The electronic device 1100 is provided with a main central processing unit (CPU) 1110 and a system controller 1120. Power is supplied to the main CPU 1110 and the system controller 1120 by different systems from a battery not illustrated, for example. The electronic device 1100 further includes a setting information holding unit 1130 including a memory and the like for holding various pieces of information set by a user. The main CPU 1110, the system controller 1120, and the setting information holding unit 1130 are configured as an integrated semiconductor device according to the present disclosure.

The main CPU 1110 includes a menu processing unit 111 which generates a menu screen for allowing the user to set various pieces of information and select an application, and an application processing unit 112 which executes the application. The set information is delivered to the setting information holding unit 1130 by the main CPU 1110 and held in the setting information holding unit 1130. The system controller 1120 includes an operation input receiving unit 121, a communication processing unit 122, and a power control unit 123. States of the operation keys 1103, the operation keys 1104, and the operation key 1105 are detected by the operation input receiving unit 121, the communication processing unit 122 performs communication processing with the external device, and the power control unit 123 controls power supplied to each unit.

### Others

Although the embodiments of the present disclosure are heretofore described specifically, the present disclosure is not limited to the above-described embodiments, and various modifications based on the technical idea of the present disclosure may be made. For example, numerical values, structures, substrates, materials, processes and the like mentioned in the above-described embodiments are merely examples, and numerical values, structures, substrates, materials, processes and the like different from those may also be used as needed.

Note that, the technology of the present disclosure may also have the following configuration.

[A1] A semiconductor device including:

a wiring board; and

a chip-shaped semiconductor element flip-chip mounted on the wiring board,

in which a plurality of solder bumps and a plurality of protrusions including an insulating material are provided on a surface of the chip-shaped semiconductor element on a side facing the wiring board, and

the chip-shaped semiconductor element is arranged so as to face the wiring board via an underfilling material in a state in which the underfilling material having a characteristic that viscosity decreases with an increase in temperature is applied to the wiring board and then subjected to reflow treatment to be flip-chip mounted on the wiring board.

[A2] The semiconductor device according to [A1] described above,

in which the chip-shaped semiconductor element includes a protrusion formed so that a tip end does not reach the wiring board in a state in which the chip-shaped semiconductor element is flip-chip mounted.

[A3] The semiconductor device according to [A1] or [A2] described above,

in which the chip-shaped semiconductor element is mounted in a state positioned with respect to the wiring board by fusion of a solder bump provided on the wiring board with the solder bumps provided on the chip-shaped semiconductor element by the reflow treatment.

[A4] The semiconductor device according to any one of [A1] to [A3] described above,

in which the underfilling material is applied collectively to the wiring board.

[A5] The semiconductor device according to any one of [A1] to [A4] described above, in which the underfilling material has a flux function.

[A6] The semiconductor device according to any one of [A1] to [A5] described above,

in which the protrusions are provided at a constant density in a region where the protrusions are arranged on the surface of the chip-shaped semiconductor element.

[A7] The semiconductor device according to any one of [A1] to [A5] described above,

in which the protrusions are provided in a region where the protrusions are arranged on the surface of the chip-shaped semiconductor element at different densities depending on positions in the region.

[A8] The semiconductor device according to [A7] described above,

in which a gap between adjacent protrusions on the surface of the chip-shaped semiconductor element is provided across the region where the protrusions are arranged.

[A9] The semiconductor device according to [A7] or [A8] described above,

in which the density of the protrusions in a central region of the surface of the chip-shaped semiconductor element is higher than the density of the protrusions in a peripheral region surrounding the central region.

[A10] The semiconductor device according to any one of [A1] to [A9] described above,

in which the protrusions of the same shape are provided on the surface of the chip-shaped semiconductor element.

[A11] The semiconductor device according to any one of [A1] to [A9] described above,

in which a plurality of types of protrusions having different shapes are provided on the surface of the chip-shaped semiconductor element.

[A12] The semiconductor device according to [A11] described above,

in which a plurality of types of protrusions of different heights are provided on the surface of the chip-shaped semiconductor element.

[A13] The semiconductor device according to any one of [A1] to [A12] described above,

in which the protrusions on the surface of the chip-shaped semiconductor element are formed to be smaller in shape with a distance from the surface of the chip-shaped semiconductor element.

[A14] The semiconductor device according to any one of [A1] to [A13] described above,

in which the protrusions on the surface of the chip-shaped semiconductor element have symmetrical shapes.

[A15] The semiconductor device according to any one of [A1] to [A13] described above,

in which the protrusions on the surface of the chip-shaped semiconductor element have asymmetrical shapes.

[B1] A chip-shaped semiconductor element flip-chip mounted on a wiring board to which an underfilling material is applied,

in which a plurality of solder bumps and a plurality of protrusions including an insulating material are provided on a surface of the chip-shaped semiconductor element on a side facing the wiring board.

[B2] The chip-shaped semiconductor element according to [B1] described above,

in which the chip-shaped semiconductor element includes a protrusion formed so that a tip end does not reach the wiring board in a state in which the chip-shaped semiconductor element is flip-chip mounted.

[B3] The chip-shaped semiconductor element according to [B1] or [B2] described above,

in which the protrusions are provided at a constant density in a region where the protrusions are arranged on the surface of the chip-shaped semiconductor element.

[B4] The chip-shaped semiconductor element according to any one of [B1] to [B3] described above,

in which the protrusions are provided in a region where the protrusions are arranged on the surface of the chip-shaped semiconductor element at different densities depending on positions in the region.

[B5] The chip-shaped semiconductor element according to [B4] described above,

in which a gap between adjacent protrusions is provided across the region where the protrusions are arranged.

[B6] The chip-shaped semiconductor element according to [B4] or [B5] described above,

in which the density of the protrusions in a central region of the surface of the chip-shaped semiconductor element is higher than the density of the protrusions in a peripheral region surrounding the central region.

[B7] The chip-shaped semiconductor element according to any one of [B1] to [B6] described above,

in which the protrusions of the same shape are provided on the surface of the chip-shaped semiconductor element.

[B8] The chip-shaped semiconductor element according to any one of [B1] to [B6] described above,

in which a plurality of types of protrusions having different shapes are provided on the surface of the chip-shaped semiconductor element.

[B9] The chip-shaped semiconductor element according to [B8] described above, in which a plurality of types of protrusions of different heights are provided.

[B10] The chip-shaped semiconductor element according to any one of [B1] to [B9] described above,

in which the protrusions are formed to be smaller in shape with a distance from the surface of the chip-shaped semiconductor element.

[B11] The chip-shaped semiconductor element according to any one of [B1] to [B10] described above,

in which the protrusions have symmetrical shapes.

[B12] The chip-shaped semiconductor element according to any one of [B1] to [B10] described above,

in which the protrusions have asymmetrical shapes.

[C1] An electronic device including a semiconductor device including a wiring board and a chip-shaped semiconductor element flip-chip mounted on the wiring board,

in which a plurality of solder bumps and a plurality of protrusions including an insulating material are provided on a surface of the chip-shaped semiconductor element on a side facing the wiring board, and

the chip-shaped semiconductor element is arranged so as to face the wiring board via an underfilling material in a state in which the underfilling material having a characteristic that viscosity decreases with an increase in temperature is applied to the wiring board and then subjected to reflow treatment to be flip-chip mounted on the wiring board.

[C2] The electronic device according to [C1] described above,

in which the chip-shaped semiconductor element includes a protrusion formed so that a tip end does not reach the wiring board in a state in which the chip-shaped semiconductor element is flip-chip mounted.

[C3] The electronic device according to [C1] or [C2] described above,

in which the chip-shaped semiconductor element is mounted in a state positioned with respect to the wiring board by fusion of a solder bump provided on the wiring board with the solder bumps provided on the chip-shaped semiconductor element by the reflow treatment.

[C4] The electronic device according to any one of [C1] to [C3] described above,

in which the underfilling material is applied collectively to the wiring board.

[C5] The electronic device according to any one of [C1] to [C4] described above,

in which the underfilling material has a flux function.

[C6] The electronic device according to any one of [C1] to [C5] described above,

in which the protrusions are provided at a constant density in a region where the protrusions are arranged on the surface of the chip-shaped semiconductor element.

[C7] The electronic device according to any one of [C1] to [C5] described above,

in which the protrusions are provided in a region where the protrusions are arranged on the surface of the chip-shaped semiconductor element at different densities depending on positions in the region.

[C8] The electronic device according to [C7] described above,

in which a gap between adjacent protrusions on the surface of the chip-shaped semiconductor element is provided across the region where the protrusions are arranged.

[C9] The electronic device according to [C7] or [C8] described above,

in which the density of the protrusions in a central region of the surface of the chip-shaped semiconductor element is higher than the density of the protrusions in a peripheral region surrounding the central region.

[C10] The electronic device according to any one of [C1] to [C9] described above,

in which the protrusions of the same shape are provided on the surface of the chip-shaped semiconductor element.

[C11] The electronic device according to any one of [C1] to [C9] described above,

in which a plurality of types of protrusions having different shapes are provided on the surface of the chip-shaped semiconductor element.

[C12] The electronic device according to [C11] described above,

in which a plurality of types of protrusions of different heights are provided on the surface of the chip-shaped semiconductor element.

[C13] The electronic device according to any one of [C1] to [C12] described above,

in which the protrusions on the surface of the chip-shaped semiconductor element are formed to be smaller in shape with a distance from the surface of the chip-shaped semiconductor element.

[C14] The electronic device according to any one of [C1] to [C13] described above,

in which the protrusions on the surface of the chip-shaped semiconductor element have symmetrical shapes.

[C15] The electronic device according to any one of [C1] to [C13] described above,

in which the protrusions on the surface of the chip-shaped semiconductor element have asymmetrical shapes.

[D1] A method of manufacturing a manufacturing method of a semiconductor device including

arranging a chip-shaped semiconductor element provided with a plurality of solder bumps and a plurality of protrusions including an insulating material on a surface on a side facing a wiring board so as to face the wiring board via an underfilling material in a state in which the underfilling material having a characteristic that viscosity decreases with an increase in temperature is applied to the wiring board, and then applying reflow treatment to flip-chip mount the chip-shaped semiconductor element on the wiring board.

[D2] The method of manufacturing the semiconductor device according to [D1] described above,

in which the chip-shaped semiconductor element includes a protrusion formed so that a tip end does not reach the wiring board in a state in which the chip-shaped semiconductor element is flip-chip mounted.

[D3] The method of manufacturing the semiconductor device according to [D1] or [D2] described above,

in which the chip-shaped semiconductor element is mounted in a state positioned with respect to the wiring board by fusion of a solder bump provided on the wiring board with the solder bumps provided on the chip-shaped semiconductor element by the reflow treatment.

[D4] The method of manufacturing the semiconductor device according to any one of [D1] to [D3] described above,

in which the underfilling material is applied collectively to the wiring board.

[D5] The method of manufacturing the semiconductor device according to any one of [D1] to [D4] described above,

in which the underfilling material has a flux function.

[D6] The method of manufacturing the semiconductor device according to any one of [D1] to [D5] described above,

in which the protrusions are provided at a constant density in a region where the protrusions are arranged on the surface of the chip-shaped semiconductor element.

[D7] The method of manufacturing the semiconductor device according to any one of [D1] to [D5] described above,

in which the protrusions are provided in a region where the protrusions are arranged on the surface of the chip-shaped semiconductor element at different densities depending on positions in the region.

[D8] The method of manufacturing the semiconductor device according to [D7] described above,

in which a gap between adjacent protrusions on the surface of the chip-shaped semiconductor element is provided across the region where the protrusions are arranged.

[D9] The method of manufacturing the semiconductor device according to [D7] or [D8] described above,

in which the density of the protrusions in a central region of the surface of the chip-shaped semiconductor element is higher than the density of the protrusions in a peripheral region surrounding the central region.

[D10] The method of manufacturing the semiconductor device according to any one of [D1] to [D9] described above,

in which the protrusions of the same shape are provided on the surface of the chip-shaped semiconductor element.

[D11] The method of manufacturing the semiconductor device according to any one of [D1] to [D9] described above,

in which a plurality of types of protrusions having different shapes are provided on the surface of the chip-shaped semiconductor element.

[D12] The method of manufacturing the semiconductor device according to [D11] described above,

in which a plurality of types of protrusions of different heights are provided on the surface of the chip-shaped semiconductor element.

[D13] The method of manufacturing the semiconductor device according to any one of [D1] to [D12] described above,

in which the protrusions on the surface of the chip-shaped semiconductor element are formed to be smaller in shape with a distance from the surface of the chip-shaped semiconductor element.

[D14] The method of manufacturing the semiconductor device according to any one of [D1] to [D13] described above,

in which the protrusions on the surface of the chip-shaped semiconductor element have symmetrical shapes.

[D15] The method of manufacturing the semiconductor device according to any one of [D1] to [D13] described above,

in which the protrusions on the surface of the chip-shaped semiconductor element have asymmetrical shapes.

### REFERENCE SIGNS LIST

1, 1A, 1B Semiconductor device
10, 10A, 10B, 10C, 10D Chip-shaped semiconductor element
11 Electrode (solder bump) of chip-shaped semiconductor element
12, 12A, 12B, 12C, 12D, 12E, 12F Protrusion
13 Gap
20 Wiring board
20A Facing portion
21 Electrode (solder bump) of wiring board
22, 22A, 22B Underfilling material
23 Electrode
30 Bonding layer
40 Bonding wire
1100 Electronic device
1101 Outer casing
1102 Display panel
1103 Operation key
1104 Operation key
1105 Operation key
1106 Terminal
1107 Supply terminal for power supply
1108 Light receiving window
1110 Main CPU
1111 Menu processing unit
1112 Application processing unit
1120 System controller
1121 Operation input receiving unit
1122 Communication processing unit
1123 Output control unit
1130 Setting information holding unit

1. A semiconductor device comprising:
a wiring board; and
a chip-shaped semiconductor element flip-chip mounted on the wiring board,
wherein a plurality of solder bumps and a plurality of protrusions including an insulating material are provided on a surface of the chip-shaped semiconductor element on a side facing the wiring board, and
the chip-shaped semiconductor element is arranged so as to face the wiring board via an underfilling material in a state in which the underfilling material having a characteristic that viscosity decreases with an increase in temperature is applied to the wiring board and then subjected to reflow treatment to be flip-chip mounted on the wiring board.

2. The semiconductor device according to claim 1,
wherein the chip-shaped semiconductor element includes a protrusion formed so that a tip end does not reach the wiring board in a state in which the chip-shaped semiconductor element is flip-chip mounted.

3. The semiconductor device according to claim 1,
wherein the chip-shaped semiconductor element is mounted in a state positioned with respect to the wiring board by fusion of a solder bump provided on the wiring board with the solder bumps provided on the chip-shaped semiconductor element by the reflow treatment.

4. The semiconductor device according to claim 1,
wherein the underfilling material is applied collectively to the wiring board.

5. The semiconductor device according to claim 1,
wherein the underfilling material has a flux function.

6. A chip-shaped semiconductor element flip-chip mounted on a wiring board to which an underfilling material is applied,
wherein a plurality of solder bumps and a plurality of protrusions including an insulating material are provided on a surface of the chip-shaped semiconductor element on a side facing the wiring board.

7. The chip-shaped semiconductor element according to claim 6,
wherein the chip-shaped semiconductor element includes a protrusion formed so that a tip end does not reach the wiring board in a state in which the chip-shaped semiconductor element is flip-chip mounted.

8. The chip-shaped semiconductor element according to claim 6,
wherein the protrusions are provided at a constant density in a region where the protrusions are arranged on the surface of the chip-shaped semiconductor element.

9. The chip-shaped semiconductor element according to claim 6,
wherein the protrusions are provided in a region where the protrusions are arranged on the surface of the chip-shaped semiconductor element at different densities depending on positions in the region.

10. The chip-shaped semiconductor element according to claim 9,
wherein a gap between adjacent protrusions is provided across the region where the protrusions are arranged.

11. The chip-shaped semiconductor element according to claim 9,
wherein a density of the protrusions in a central region of the surface of the chip-shaped semiconductor element is higher than a density of the protrusions in a peripheral region surrounding the central region.

12. The chip-shaped semiconductor element according to claim 6,
wherein the protrusions of the same shape are provided on the surface of the chip-shaped semiconductor element.

13. The chip-shaped semiconductor element according to claim 6,
wherein a plurality of types of protrusions having different shapes are provided on the surface of the chip-shaped semiconductor element.

14. The chip-shaped semiconductor element according to claim 13,
wherein a plurality of types of protrusions of different heights are provided.

15. The chip-shaped semiconductor element according to claim 6,
wherein the protrusions are formed to be smaller in shape with a distance from the surface of the chip-shaped semiconductor element.

16. The chip-shaped semiconductor element according to claim 6,
wherein the protrusions are symmetrical.

17. The chip-shaped semiconductor element according to claim 6,
wherein the protrusions are asymmetrical.

18. An electronic device comprising
a semiconductor device including a wiring board and a chip-shaped semiconductor element flip-chip mounted on the wiring board,
wherein a plurality of solder bumps and a plurality of protrusions including an insulating material are provided on a surface of the chip-shaped semiconductor element on a side facing the wiring board, and
the chip-shaped semiconductor element is arranged so as to face the wiring board via an underfilling material in a state in which the underfilling material having a characteristic that viscosity decreases with an increase in temperature is applied to the wiring board and then subjected to reflow treatment to be flip-chip mounted on the wiring board.

19. A method of manufacturing a semiconductor device, comprising
arranging a chip-shaped semiconductor element provided with a plurality of solder bumps and a plurality of protrusions including an insulating material on a surface on a side facing a wiring board so as to face the wiring board via an underfilling material in a state in which the underfilling material having a characteristic that viscosity decreases with an increase in temperature is applied to the wiring board, and then applying reflow treatment to flip-chip mount the chip-shaped semiconductor element on the wiring board.
